(19) United States
(12) Patent Application Publication
(10) Pub. No.: US 2005/0106774 A1
(43) Pub. Date: May 19, 2005

(54) Surface processes in fabrications of microstructures

(76) Inventors: Dmitri Simonian, Sunnyvale, CA (US); John D. Porter, Berkeley, CA (US)

Correspondence Address: REFLECTIVITY, INC., 350 POTRERO AVENUE, SUNNYVALE, CA, 94085, US

(21) Appl. No.: 10/713,671

(22) Filed: Nov. 13, 2003

(51) Int. Cl. H01L 21/00; H01L 21/302; H01L 21/461

(52) U.S. Cl. 438/51; 438/745

(57) ABSTRACT

A method for altering surfaces of a microstructure is disclosed. The modification comprises cleaning the surfaces using an ozone-containing cleaning agent. The modification may also comprise coating the surfaces of the microstructure using a vapor phase coating agent that reacts chemically with the surface. The modification may also comprise coating the surfaces of the microstructure using a lubricant that interacts physically with the surface. The modification can be performed after removal of sacrificial materials of the microstructure during the fabrication process. In particular, the modification method is applicable during the packaging stage for the microstructure.

### TECHNICAL FIELD OF THE INVENTION

The present invention is related generally to the art of fabrication of microstructures and, more particularly, to surface preparation in fabrication of the microstructures.

### BACKGROUND OF THE INVENTION

Microstructures, such as microelectromechanical devices, have found many applications in basic signal transduction. For example, a spatial light modulator based on a microelectromechanical device steers light in response to electrical or optical signals. Such a modulator can be a part of a communication device or an information display.

A major factor that limits the reliability and widespread use of microelectromechanical devices is adhesion. Adhesion is a result of the dominance of surface and interfacial forces, such as capillary, chemical bonding, electrostatic, and van der Waals forces, over mechanical forces which tend to separate microelectromechanical components. When mechanical restoring forces cannot overcome adhesive forces, the microelectromechanical devices are said to suffer from stiction. Stiction failures in contacting microstructures, such as micromirror devices, can occur after the first contacting event (often referred to as initial stiction), or as a result of repeated contacting events (often referred to as in-use stiction). Initial stiction is often associated with surface contamination (e.g., residues of bonding materials or photoresist), or with high energy of contacting surfaces (e.g., clean oxidized silicon or metallic surfaces). For the case of in-use stiction, each time one part of the microstructure (e.g. mirror plate of a micromirror device) touches the other (e.g. stopping mechanism) or the substrate, the contact force grows and ultimately becomes too large for the restoring force to overcome. In this case, the device remains in one state indefinitely. This phenomenon can arise from a variety of underlying mechanisms, such as contact area growth, creation of high-energy surface by micro-wear, surface charge separation etc.

An approach to reduce stiction is to use surface chemical reactions to form a low-energy coating on surfaces of microstructures. In this way, the surface and interfacial forces can be reduced in contact areas of microelectromechanical devices.

### SUMMARY OF THE INVENTION

In an embodiment of the invention, a method for modifying a surface of a microelectromechanical device is disclosed. The method comprising: loading the microelectro-mechanical device into a chamber; preparing a cleaning agent comprising ozone gas and a co-agent that comprises oxygen-containing molecules; and introducing the prepared cleaning agent into the chamber, for cleaning the surface of the microelectromechanical device in the chamber.

In another embodiment of the invention, a method for modifying a surface of a microelectromechanical device that is assembled within an assembly is disclosed. The method comprises: loading the assembly into a chamber; preparing a gaseous modification agent; and introducing the gaseous modification agent into the chamber such that the cleaning agent is delivered through a micro-opening of the assembly to the surface of the microelectromechanical device for modifying the surfaces of the microelectromechanical device, wherein the micro-opening has a characteristic dimension around 10 micrometers or less.

In yet another embodiment of the invention, a method for modifying a surface of a microelectromechanical device is disclosed. The method comprises: assembling the microelectromechanical device into an assembly that comprises at least two substrates, one of which is opaque to ultra-violet light; loading the assembly into a chamber; preparing a gaseous modification agent; and introducing the gaseous modification agent into the chamber for modifying the surface of the microelectromechanical device.

In yet another embodiment of the invention, a method for modifying a surface of a microelectromechanical device in an assembly is disclosed. The method comprises: loading the assembly into a chamber; and introducing a gaseous modification agent into the chamber such that the agent is delivered through an opening of the assembly to the surface of the microelectromechanical device, further comprising: a) introducing a first component of the agent into the chamber at a first pressure; and b) introducing a second component of the agent into the chamber at a second pressure that is higher than the first pressure.

In yet another embodiment of the invention, a method for processing a surface of a microelectromechanical device during a packaging process for the microelectro-mechanical device is disclosed. The method comprising: assembling the microelectro-mechanical device into an assembly; attaching the assembly to a packaging substrate; loading the package substrate attached with the assembly into a chamber; preparing a cleaning agent comprising ozone gas and an oxygen containing co-agent; introducing the prepared cleaning agent into the chamber for cleaning the surface of the microelectromechanical device in the chamber; and sealing the microelectromechanical device between the package substrate and a cover lid by bonding the cover lid to the substrate.

In yet another embodiment of the invention, a method for processing a surface of a microelectromechanical device during a packaging process for the microelectro-mechanical device is disclosed. The method comprises: assembling the microelectro-mechanical device into an assembly; attaching the assembly to a packaging substrate; loading the package substrate attached with the assembly into a chamber; preparing a gaseous modification agent; and introducing the gaseous modification agent into the chamber such that the cleaning agent is delivered through an micro-opening of the assembly to the surface of the microelectromechanical device for modifying the surfaces of the microelectromechanical device, wherein the micro-opening has a characteristic dimension around 10 micrometers or less; and sealing the microelectromechanical device between the package substrate and a cover lid by bonding the cover lid to the substrate.

In yet another embodiment of the invention, a method for cleaning a surface of a microelectromechanical device, the method comprising: loading the microelectro-mechanical device into a chamber; and cleaning the surfaces of the microelectro-mechanical device in the chamber using a cleaning agent that comprises ozone gas.

In yet another embodiment of the invention, a method for processing a surface of a microelectromechanical device during a packaging process for the microelectro-mechanical device, the method comprising: assembling the microelectromechanical device into an assembly that comprises at least two substrates, one of which is opaque to ultra-violet light; attaching the assembly to a packaging substrate; loading the package substrate attached with the assembly into a chamber; preparing a gaseous modification agent; and introducing the gaseous modification agent into the chamber for modifying the surface of the microelectromechanical device.

In yet another embodiment of the invention, a system for modifying a microelectromechanical device, the system comprising: a cleaning agent chamber containing ozone gas; a co-agent source containing an oxygen containing co-agent; a coating source containing a coating agent; and a chamber that is connected to the cleaning source, the co-agent source and the coating source.

### BRIEF DESCRIPTION OF DRAWINGS

While the appended claims set forth the features of the present invention with particularity, the invention, together with its objects and advantages, may be best understood from the following detailed description taken in conjunction with the accompanying drawings of which:

FIG. 1a and FIG. 1b are cross-sectional views schematically illustrating a micromirror device, specifically, FIG. 1a illustrating the micromirror after release and FIG. 1b illustrating the micromirror in operation;

FIG. 2a and FIG. 2b are cross-sectional views schematically illustrating another micromirror device, specifically, FIG. 2a illustrating the micromirror after release and FIG. 2b illustrating the micromirror in operation;

FIG. 3 schematically illustrates a cross-sectional view of a microstructure assembly that comprises: a substrate with microstructures formed on its surface joined to another substrate to form a panel with a gap between the two substrates such that gas inside the panel can exchange with the gas outside the panel via a micro-opening having a characteristic dimension around 10 micrometers or less;

FIG. 4 is a perspective view of the microstructure assembly before the two substrates are bonded;

FIG. 5 is a block diagram schematically illustrating a system for gas-phase cleaning and coating of microstructure surfaces; and

FIG. 6 is a flow chart showing steps executed in processing the surface of the microstructure according to an embodiment of the invention.

### DETAILED DESCRIPTION OF THE EMBODIMENTS

The present invention provides a method for cleaning and/or coating and/or lubricating the surfaces of microstructures. In the cleaning process, a cleaning agent, such as a gas mixture containing ozone, is applied to the surface to remove contaminants, such as organic residues on the surface. In an embodiment of the invention, the cleaning agent comprises humid ozone gas and dry ozone gas. “Humid ozone gas”, is a mixture of water vapor and ozone gas. “Dry ozone gas”, is ozone gas without significant amounts of water vapor. In the coating process, one or more vapor phase agents are introduced to the surface of the microstructure. The coating agents react with the surface to form a chemically bonded surface layer.

The method of the present invention is particularly useful in altering partly enclosed surfaces, such as a surface of a microstructure in an assembly that comprises: a substrate with microstructures formed on its surface joined to another substrate to form a panel with a gap between the two substrates such that gas inside the panel can exchange with the gas outside the panel via a “micro-opening” having a characteristic dimension around 10 micrometers or less. Of course, the invention is applicable to microstructures without such micro-openings. The cleaning agent is applied onto the surface via the micro-opening. As an aspect of the invention, a pressure cycle is provided to expedite the cleaning process. The cleaning cycle comprises three steps: a) filling a first component of the cleaning agent into the chamber to a first pressure, b) filling the chamber with a second component of the cleaning agent to a second pressure that is higher than the first pressure and c) reducing the pressure inside the chamber to a third pressure that is lower than the first pressure. These steps can be repeated during the cleaning process as many times as necessary for cleaning to occur. The cleaning method is particularly useful for cleaning a surface located within an assembly that is not transmissive to ultra-violet light, for which standard UV/ozone cleaning techniques are not applicable.

This type of pressure cycling may also be employed in the coating process. Specifically, a first component of the coating agent is introduced into the chamber at a first pressure. Then, optionally, a second component of the coating agent is introduced into the chamber at a second pressure that is higher than the first pressure. In this way, a transient pressure gradient between the inside space of the assembly and the rest of the chamber is created. This transient pressure gradient facilitates gas flow through a micro-opening into the assembly.

The coating process is preferably conducted by diluting coating agents with a carrier gas, which is used to facilitate the flow of the vapor phase coating agent. The carrier gas can be an inert gas.

Both cleaning and coating processes of the invention can be conducted during the packaging stage of the fabrication, especially when contamination (e.g. from adhesive materials) can occur prior to the packaging process. Conducting the cleaning and coating processes during the packaging stage reduces or eliminates surface contamination. A further advantage of the method is the allowance of the cleaning and coating process to be conducted sequentially in the same chamber, in which way contamination of the microstructure, otherwise possible between the cleaning and the coating processes, does not occur.

The method of the present invention is applicable to a variety of microstructures, such as microstructures with a movable element (e.g. hinged micromirrors). In the following, the present invention will be discussed in detail, with reference to embodiments in which surfaces of micromirrors are modified during the packaging stage, and the micromirror is assembled into an assembly that comprises two substrates, one of which is transmissive to visible light. It will be appreciated by those ordinarily skilled in the art that the following discussion is for simplicity and demonstration purposes only. It should not be interpreted in any way as a limitation. Rather, other variations of the embodiments without departing from the spirit of the present invention are also applicable. For example, the present invention can be applied to alter surfaces in other types of microstructures (e.g. microelectromechanical switches operate in radio-frequency, Microvalves, pressure micro-sensors, optical switches etc.).

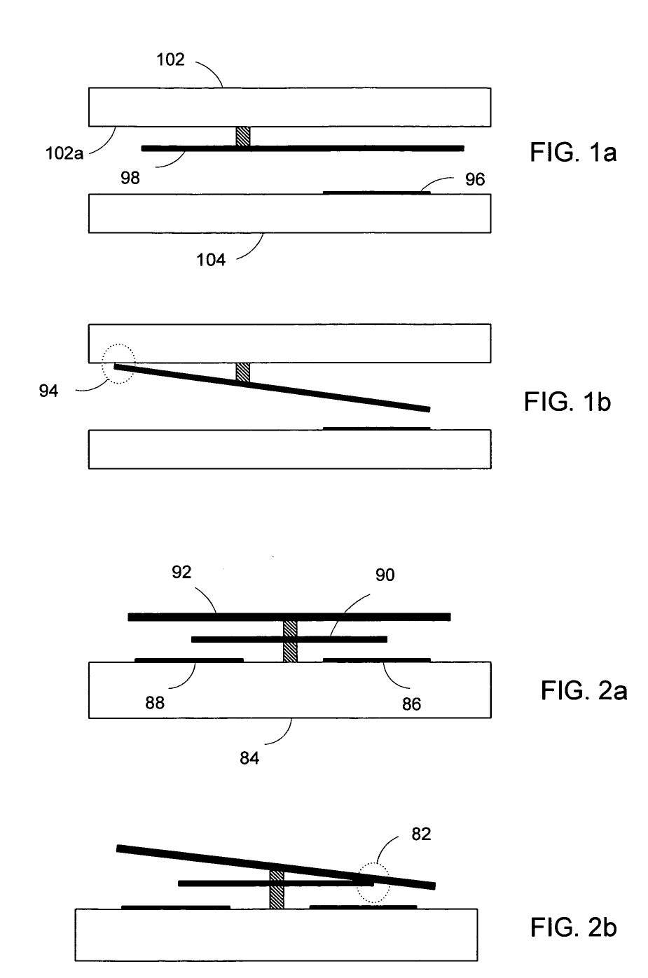

Turning to the drawings, FIG. 1a illustrates a cross-sectional view of an exemplary micromirror device after releasing the micromirror by removing sacrificial materials from the micromirror. Mirror plate 98, which is formed on substrate 102, is located between substrate 102 and substrate 104 that comprises electrode 96 formed thereon. In this particular example, substrate 102 is comprised of glass that is transmissive to visible light and opaque to ultra-violet light.

In operation, the mirror plate switches between an ON state and an OFF state in response to an electrostatic force applied between the mirror plate and the electrode so as to generate desired patterns in a display target by reflecting incident light onto or away from the display target. The OFF state is a state wherein the mirror plate is substantially parallel to the substrate, as shown in FIG. 1a. The ON state is defined to be a state in which the mirror plate is rotated to an ON state angle, wherein one end of the mirror plate impacts against a stopping mechanism, such as area 102a on substrate 102, as shown in FIG. 1b. The contact of the mirror plate and the stopping mechanism results in the existence of contact areas, such as contact area 94.

The mirror plate may experience in-use stiction due to interfacial forces between the surfaces of the substrate and the mirror plate at the contact area. Specifically, when the applied electrostatic field is decreased, to let the mirror plate resume its non-deformed state (e.g. the OFF state), the mirror plate is not able to do so when the internal restoration force of the micromirror does not overcome the interfacial stiction force. The same situation can occur in other types of micromirror devices, such as the micromirror device in FIG. 2a and FIG. 2b.

Referring to FIG. 2a, a cross-sectional view of a micromirror is illustrated therein. Mirror plate 92 and electrodes 88 and 86 are formed on the same substrate 84, which is a silicon wafer. Stopper 90 is provided as the stopping mechanism for defining the ON state and the OFF state of the micromirror. In operation, the mirror plate rotates to an ON state angle and an OFF state angle in response to electrostatic forces between the mirror plate and the electrodes to reflect incident light into different spatial directions. The rotation of the mirror plate is stopped by stopper 90 and the lower surface of the mirror plate contacts the upper surface of the stopper at contact area 82. When the electrostatic force intentionally applied to the mirror plate does not overcome the interfacial forces between the surfaces of the mirror plate and the stopper, the mirror plate will not be able to switch from one rotation state to another.

In order to reduce interfacial forces so as to eliminate or alleviate in-use stiction, surfaces of the micromirror, especially the contact surfaces of the mirror plate and the stopping mechanisms (e.g. substrate 102 in FIG. 1b and stopper 90 in FIG. 2b), are chemically modified. The modification may comprise separate processes, such as cleaning, coating and/or lubricating.

The cleaning process removes contaminants, such as residues from organic bonding materials at the surfaces (e.g. the surfaces of the mirror plate, substrate and stopping mechanisms) of the micromirror. These surfaces may be located underneath other structures of the micromirror. In the cleaning process, one or more cleaning agents are introduced onto the surfaces, including the surfaces underneath other structures.

In an embodiment of the invention, ozone-containing gas is used, possibly in conjunction with a gaseous co-agent. As an aspect of the invention, humid ozone gas and dry ozone gas are used as cleaning agents. For example, the cleaning process using ozone can efficiently remove organic contaminants, such as organic residues from bonding materials that are often introduced onto the surfaces during the packaging stage. Moreover, the cleaning process does not require ultra-violet light that is often used in cleaning the surfaces of microstructures disclosed in prior art. In particular, when a glass substrate is used, such as the glass substrate in micromirror device in FIGS. 1a and 1b, ultra-violet light can not substantially penetrate the glass substrate and shine on the surface to be cleaned. In this situation, the cleaning process of the present invention becomes more important.

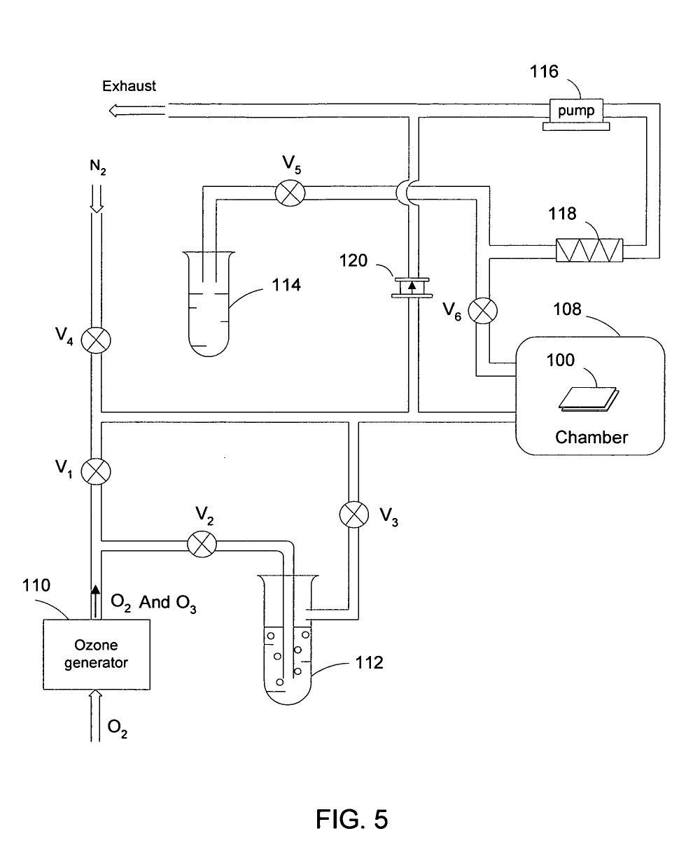

The cleaning process starts by loading the microstructure assembly into a chamber, such as chamber 108 in FIG. 5, which will be discussed in more detail, below. As an aspect of the embodiment, the cleaning process consists of two cleaning stages. In one stage, humid ozone gas is generated by flowing oxygen gas through an ozone generator and then saturating the generated ozone gas with water vapor at a temperature T₁. The resulting humid ozone gas is provided to the surfaces of the device, which are kept at temperature T₂. In an embodiment of the invention, T₁ is preferably at or below room temperature and T₂ is preferably between 100° C. and 200° C. The chamber is filled with wet ozone to a first pressure, which is preferably between 1 Torr and 2000 Torr. Of course, a pressure higher than 2000 Torr may also be employed.

In the subsequent cleaning stage, dry ozone gas is introduced into the chamber and applied to the surfaces of the microstructure. The chamber is filled with dry ozone to a second pressure greater than the first pressure and preferably between 100 Torr and 5000 Torr.

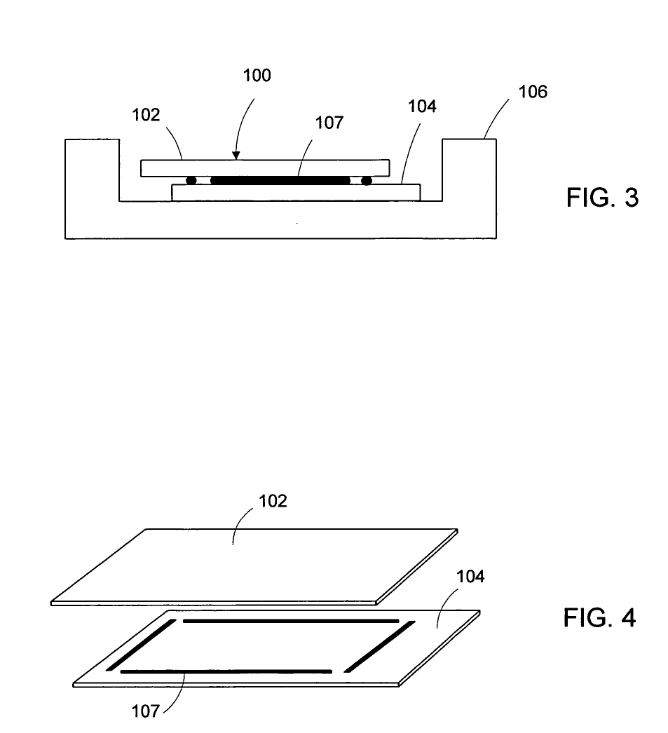

The cleaning process is conducted after micromirror release. In particular, it can be performed to clean the surfaces of the micromirror within an assembly during the packaging stage, which will be discussed in the following with reference to FIG. 3 and FIG. 4.

Referring to FIG. 3, micromirror assembly 100 comprises two substrates 102 and 104. In this example, substrate 102 is glass that is transparent to visible light and not transparent to ultra-violet light. The micromirror array is formed on the glass substrate 102. Substrate 104 is a silicon wafer having one or more electrodes and circuitry that are associated with the micromirrors on substrate 102 for controlling the rotations of the micromirrors.

The packaging process begins with bonding the two substrates together using a selected bonding material 107. An exploded perspective view of the two substrates, with the bonding material applied to substrate 104, is illustrated in FIG. 4. Referring to FIG. 4, bonding material 107 is dispensed around the circumference of substrate 104. In this particular example, the bonding material is not a continuous line around the circumference of the device. Discontinuities in the dispensed bonding material create micro-openings in the assembled device. The smaller dimension of a micro-opening is around 10 micrometers or less, or 5 micrometers or less. In other embodiments of the invention, the micro-openings may have a larger size, such as 10 micrometers or more. The bonding material may also be deposited on substrate 102, or on both of the substrates 102 and 104. During the bonding process, the bonding material can outgas or creep, and light organic components (e.g., solvents) will adsorb or diffuse onto the surfaces of the microstructure, creating a contaminated layer. As a result of the bonding, the micromirrors formed on substrate 102 and the electrodes and circuitry on substrate 104 are partly enclosed within the assembly of the substrates and the bonding material, as shown in FIG. 3.

Referring again to FIG. 3, assembly of the substrates creates micro-openings between the bonded substrates. These micro-openings allow for the cleaning agents to flow through and contact the partly enclosed surfaces of the micromirrors and substrates. The assembly is attached to package substrate 106, which is typically comprised of ceramic, and/or metal and/or glass. The package substrate may have other features, such as a built-in heater on or buried underneath the surfaces of the package.

In order to efficiently clean the partly enclosed surfaces within the assembly, application of the gaseous cleaning agent is accomplished through one or more pressure cycles. Specifically, a first component of the cleaning agent, such as humid ozone gas, is introduced onto the partly enclosed surfaces through the micro-opening such that the pressure inside the chamber containing the micromirror is at the first pressure value, preferably from 1 Torr to 2000 Torr. Then a second component of the cleaning agent, such as dry ozone gas, is introduced into the chamber and applied onto the surfaces through the micro-opening such that the pressure inside the chamber is at a second pressure that is higher than the first pressure value, preferably between 100 Torr and 5000 Torr. After a time period, the chamber is pumped out so that the pressure inside the chamber reaches a third pressure value that is equal to or less than the first pressure value. These cleaning stages are repeated for a number of times until the contaminants are substantially removed from the partly enclosed surfaces of the micromirror device. Through the application of the pressure cycling, fresh cleaning agents can be transported efficiently to the surfaces of the micromirror through the micro-opening, and the products of cleaning reactions can be removed efficiently from the interior surfaces of the device. Moreover, the pressure cycling benefits provision of enough cleaning agent onto the surface through the micro-opening, especially when the internal volume of the assembly is small.

Subsequent to or along with the cleaning process, other surface modification, such as coating and lubrication may be performed. In an embodiment of the invention, a coating process is executed following the cleaning process. The coating process is preferably executed within the same chamber in which the surfaces are cleaned using the above-described cleaning method. In this way, contamination that may occur during the transfer of the cleaned microstructure from one chamber to the other, is eliminated.

The coating process employs a coating agent that can react with the surfaces of the device, thereby forming a beneficial coating layer on the surface, wherein the coating layer is chemically bonded to the surface, preferably via covalent chemical bonds. It is further preferred that the molecules of the coating agent chemically react with each other and/or a co-agent to form a chemically bonded network. The coating agent is preferably selected from a group comprising: fatty acid (e.g. long-chain n-alkanoic acid), organosilane, organosulfur compound (e.g. alkanethiolates, thiophenol, thiocarbamate and mercaptopyridine), alkyl halides, multilayers of organophosphates, perfluoropolyether or carboxylate perfluoropolyether, fluorocarbon. Exemplary organosilanes include alkylhalosilanes, such as chlorotrimethylsilane, alkylalkoxysilanes and alkylaminosilanes. The coating agent can also be a carboxylic acid material having the formula CF₃(CF₂)ₐ(CH₂)_{b}COOH, wherein a is greater than or equal to 0, and b is greater than or equal to 0, or a fluorocarbon material having the formula CₙHₘF₍₂ₙ₊₂₋ₙ₎, wherein n is greater than or equal to 1, and m is greater than or equal to 0 and less than (2n+2), or a fluorocarbon amine material having the formula N(CₙHₘF₍₂ₙ₊₁₋ₘ₎)₃ wherein n is greater than or equal to 1 and m is greater than 0.

After cleaning, surfaces of the microstructure chemically react with the coating agents to form a monomolecular, or thicker, layer of coating material on the surface. In most situations, the coating agent does not chemically react with the surface when the surface is contaminated. This is also a reason why a cleaning process is necessary.

The coating agent is provided into the chamber and introduced onto the surfaces after the cleaning process. When surfaces are terminated by —OH groups, for example, the molecules of the coating agent can react with the surface to form surface esters, surface ethers or surface oxides, in which the coating agent is covalently bonded to the surface via an oxygen atom. If coating agent molecules have more than one reactive group, they can react with each other or other co-agents, forming a chemically bonded network on the surface.

By way of example, consider an alkyltrichlorosilane, used as the coating agent, to coat a silicon surface which has been terminated by —OH groups during the cleaning process. When an alkyltrichlorosilane molecule arrives at the surface, it can enter into a displacement reaction with the —OH groups terminating the silicon surface, to form a surface Si—O—SiRCl₂ specie. The surface-bound alkyldichlorosilane fragment can react with other surface —OH groups, or surface water, and adjacent surface alkylchlorosilane fragments, to form a surface-bound polysiloxane network.

Other —OH -terminated surfaces, such as the surfaces of hydrated titania or alumina, can be made to react in a similar fashion with alkylhalosilane, or other coating agents, to form covalently-bound surface coatings.

In applying the coating agent, a carrier gas, preferably an inert gas, such as N₂, He, Ne, Ar, Kr, and Xe, may be mixed with the vapor of the coating precursor and provided onto the surfaces of the microstructure devices. A co-agent, such as water vapor, may be added to the reaction chamber prior to or following the introduction of the coating agent.

Referring to FIG. 5, the system comprises chamber 108 for containing assembly 100 in FIG. 4. The chamber is connected to ozone generator 110 via valve V₁ and meanwhile, to the outlet of water tank 112 via valve V₃, wherein the inlet of the water tank is connected to the ozone generator via valve V₂. The water tank contains water, either with the water level above its inlet, as shown in FIG. 5, such that ozone gas from the ozone generator enters the water tank below the water level and bubbles to the surface, or with the water level below its inlet, such that ozone gas from the ozone generator passes through the head space of the water tank. Humid ozone gas can be directed into the chamber from the outlet of the water tank. Alternatively, a separate water vapor source can be employed instead of the water tank. In this case, the vapor phase water can be introduced into the chamber and mixed with the ozone gas.

The chamber is also connected to container 114 that contains the coating precursor via valves V₅ and V₆. In one embodiment of the invention, a carrier gas source such as N₂ is connected to the chamber via valve V₄ such that the ozone gas can be mixed with the carrier gas. The system may comprise further components, such as filter 118, which can be an alumina trap for trapping excess coating agent.

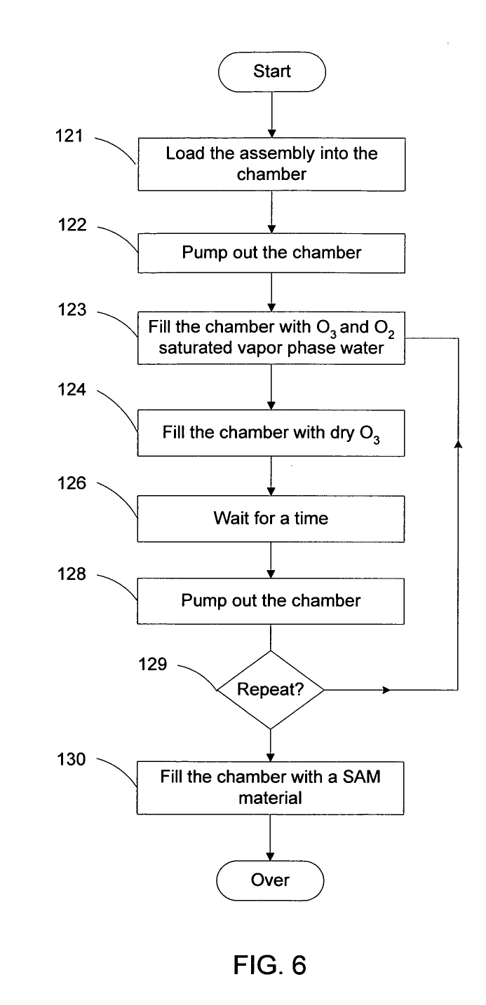

Referring to FIG. 6, a flow chart having steps executed in the modification of the surfaces of the microstructure of the present invention is illustrated therein. The assembly having the microstructures (e.g. micromirrors) partly enclosed between the bonded substrates is loaded into the chamber (step 121). The chamber is then pumped out (step 122), and filled with humid ozone gas (step 123) to a first pressure. The temperature of the chamber is preferably between 100° C. and 200° C. This step is accomplished by the following sub-steps. Oxygen gas O₂ is input into the ozone generator, in which a portion of that gas is converted to ozone gas. The output of the ozone generator, having both ozone gas and oxygen gas, is directed to the water tank so as to humidify the ozonated oxygen. Humid ozone gas flows into the chamber, the assembly and onto the surfaces of the microstructures and the substrates through the micro-openings provided for cleaning the surfaces.

After providing humid ozone gas to the chamber, dry ozone gas can also be fed into the chamber (step 124). This is accomplished by feeding the ozone gas output from the ozone generator directly into chamber 108, via valve V₁. After providing dry ozone gas to the chamber, the pressure inside the chamber reaches a second value, higher than the first pressure. In one embodiment of the invention, the pressure inside the chamber after feeding the dry ozone gas is preferably between 100 Torr and 5000 Torr, preferably around 760 Torr.

Following the introduction of dry ozone gas, the chamber is allowed to stand in its pressurized state, to allow the cleaning process to proceed (step 126). During this time, the cleaning agents clean the partly enclosed surfaces, by reacting with contaminants on the surfaces to produce volatile reaction products. At the same time, the cleaning agents tend to react with the surfaces so as to terminate the surfaces with —OH groups.

Providing sufficient gaseous cleaning agents to remove macroscopic amounts of contaminants is achieved by repeating the pumpout/refill sequence a number of times. This pressure cycling also removes volatile products of the cleaning reaction and prevents them from building up in the finished device. Specifically, step 129 determines whether to repeat the steps 123 through 128. If so, the process loops back to step 123. Steps 123 through 128 can be repeated several times as desired.

After step 126, the coating process is performed at steps 128 and 130. Specifically, the chamber is pumped out to remove water vapor and bulk water physisorbed on surfaces (step 128). The temperature of the chamber is preferably reduced to 120° C. The coating precursor, possibly with a carrier gas, is fed into the chamber and raises the pressure inside the chamber to around 760 torr (step 130). The coating precursor flows through the micro-openings of the assembly and react with the surfaces. As an example, consider the coating precursor trichloromethylsilane. After the coating process, the methylsilyl head-group of the coating agent is covalently bonded to the surface through an oxygen atom, and the oxygen atom is connected to the silicon atom of the surface through a covalent bond. The silicon atoms of neighboring hydrolyzed coating molecules are also interconnected via covalent bonds with oxygen atoms. As a result, the surface is covered by a thin, polymethylsiloxane-like layer. In other embodiments, other coating precursors and co-agents may give rise to coatings of different thickness, different type of bonding to the surface and different film morphology, depending upon the precursor and the condensation mechanism of the precursor on the surface.

After the surfaces are coated with the coating material, the packaging process can be finalized by covering a package lid on the package substrate and hermetically sealing the package lid with the package substrate.

In another embodiment of the invention, gaseous lubricant is conducted to the surfaces of the microstructure after the cleaning process (preferably without exposing to ambient). The lubricant forms a film on the surface but is not chemically bonded to the molecules of the surface. The lubricant film on the surface can mechanically dampen the microstructure momentum during contacting event and prevent plastic deformation of the contacts, and associated increase in stiction force. In this embodiment, surface coating process may not be necessary. The assembly having the microstructure can be hermetically sealed to finalize the packaging process.

In yet another embodiment of the invention, the lubrication process is conducted after the surface coating process. Specifically, after coating the surface with the coating agent following the cleaning process, a lubricant is introduced into the chamber and applied to the surface so as to form a lubrication film. After lubrication, the assembly having the micromirror can be hermetically sealed to finalize the packaging process.

It will be appreciated by those of skill in the art that a new and useful method for modifying the surfaces of microelectromechanical devices has been described herein. In view of the many possible embodiments to which the principles of this invention may be applied, however, it should be recognized that the embodiments described herein with respect to the drawing figures are meant to be illustrative only and should not be taken as limiting the scope of invention. For example, those of skill in the art will recognize that the illustrated embodiments can be modified in arrangement and detail without departing from the spirit of the invention. Therefore, the invention as described herein contemplates all such embodiments as may come within the scope of the following claims and equivalents thereof.

1. A method for modifying a surface of a microelectromechanical device, the method comprising:
loading the microelectromechanical device into a chamber;
preparing a cleaning agent comprising ozone gas and a co-agent that comprises oxygen-containing molecules; and
introducing the prepared cleaning agent into the chamber, for cleaning the surface of the microelectromechanical device in the chamber.

2. The method of claim 1, wherein the step of preparing the cleaning agent further comprises:
mixing ozone gas with the oxygen-containing co-agent that is water vapor.

3. The method of claim 1, wherein the step of preparing the cleaning agent further comprises:
mixing ozone gas with the oxygen-containing co-agent that is hydrogen peroxide vapor.

4. The method of claim 1, wherein the step of preparing the cleaning agent further comprises:
mixing ozone gas with the oxygen-containing co-agent that is acetic acid vapor.

5. The method of claim 1, wherein the step of preparing the cleaning agent further comprises:
mixing ozone gas with one or more oxygen-containing co-agents selected from a group comprising water vapor, hydrogen peroxide vapor and acetic acid vapor.

6. The method of claim 1, wherein the temperature of the chamber is between 40° C. and 400° C.

7. The method of claim 1, wherein the temperature of the chamber is between 100° C. and 200° C.

8. The method of claim 1, wherein the pressure inside the chamber is between 1 Torr and 5000 Torr.

9. The method of claim 1, further comprising:
preparing a coating agent; and
introducing the coating agent into the chamber for coating the surface of the microelectromechanical device.

10. The method of claim 4, further comprising:
pumping out the chamber before introducing the coating agent into the chamber.

11. The method of claim 4, wherein the step of preparing the coating agent further comprises:
preparing the coating agent such that after introducing the agent into the chamber, the agent forms a coating layer that is chemically bonded to the surface of the microelectromechanical device.

12. The method of claim 4, wherein the step of preparing the coating agent further comprises:
preparing the coating agent such that after introducing the agent into the chamber, the agent forms a coating layer that is physically adsorbed on the surface of the microelectromechanical device.

13. The method of claim 4, wherein the step of preparing the coating agent further comprises:
preparing the coating agent that comprises a first and second coating components such that after introducing the coating agent into the chamber, the first component of the coating agent forms a coating layer that is chemically bonded to the surface of the microelectromechanical device, and the second component of the coating agent forms another layer that is not chemically bonded to the surface of the microelectromechanical device.

14. The method of claim 1, wherein the step of introducing the cleaning agent into the chamber further comprises:
a) introducing a first component of the cleaning agent into the chamber such that the pressure inside the chamber is at a first pressure value; and
b) introducing a second component of the cleaning agent into the chamber such that the pressure inside the chamber is at a second pressure value that is higher than the first pressure value.

15. The method of claim 8, wherein the first pressure is from 1 Torr to 700 Torr.

16. The method of claim 8, wherein the second pressure is from 10 Torr to 5000 Torr.

17. The method of claim 8, further comprising:
lowering the pressure inside the chamber to a pressure less than the first pressure value; and
repeating the steps a) and b).

18. The method of claim 8, wherein the first component of the cleaning agent comprises ozone gas and water vapor.

19. The method of claim 8, wherein the second component of the cleaning agent comprises ozone gas in the absence of water.

20. The method of claim 4, wherein the step of introducing the coating agent into the chamber further comprises:
a) introducing a first component of the coating agent into the chamber such that the pressure inside the chamber is at a first pressure value; and
b) introducing a second component of the coating agent into the chamber such that the pressure inside the chamber is at a second pressure value that is higher than the first pressure value.

21. The method of claim 12, further comprising:
pumping out the chamber before introducing the first or the second component of the coating agent into the chamber.

22. The method of claim 12, further comprising:
lowering the pressure inside the chamber to a value less than the first pressure value; and
repeating steps a) and b).

23. The method of claim 4, wherein the coating agent comprises an organosilane.

24. The method of claim 4, wherein the coating agent is an organochlorosilane.

25. The method of claim 4, wherein the coating agent is a halogen-substituted organochlorosilane.

26. The method of claim 4, wherein the coating agent comprises perfluoropolyether.

27. The method of claim 4, wherein the coating agent is selected from a group comprising: a carboxylic acid material having the formula CF₃(CF₂)ₐ(CH₂)_{b}COOH, wherein a is greater than or equal to 0, and b is greater than or equal to 0; a fluorocarbon material having the formula CₙHₘF₍₂ₙ₊₂₋ₘ₎, wherein n is greater than or equal to 1, and m is greater than or equal to 0 and less than (2n+2); a fluorocarbon amine material having the formula N(CₙHₘF₍₂ₙ₊₁₋ₘ₎)₃ wherein n is greater than or equal to 1 and m is greater than or equal to 0 and less than (2n+1); a fluorocarbon ether material having the formula O(CₙHₘF₍₂ₙ₊₁₋ₘ₎)₂ wherein n is greater than or equal to 1 and m is greater than or equal to 0 and less than (2n+1).

28. The method of claim 4, wherein the temperature is from 60° C. to 300° C.

29. The method of claim 4, wherein the temperature is from 100° C. to 200° C.

30. The method of claim 4, wherein the pressure is from 1 Torr to 760 Torr.

31. A method for modifying a surface of a microelectromechanical device that is assembled within an assembly, the method comprising:
loading the assembly into a chamber;
preparing a gaseous modification agent; and
introducing the gaseous modification agent into the chamber such that the cleaning agent is delivered through a micro-opening of the assembly to the surface of the microelectromechanical device for modifying the surfaces of the microelectromechanical device, wherein the micro-opening has a characteristic dimension around 10 micrometers or less.

32. The method of claim 31, wherein the gaseous modification agent comprises a cleaning agent that cleans the surface after being introduced onto the surface of the microelectromechanical device.

33. The method of claim 32, wherein the cleaning agent comprises ozone gas.

34. The method of claim 33, wherein the cleaning agent comprises an oxygen-containing co-agent.

35. The method of claim 34, wherein the co-agent comprises vapor water.

36. The method of claim 32, further comprising:
introducing a coating agent into the chamber such that the coating agent is delivered through the micro-opening to the surface for coating the surface of the microelectromechanical device.

37. The method of claim 36, wherein the coating agent forms a layer that is chemically bonded to the surface of the microelectromechanical device.

38. The method of claim 36, wherein the coating agent forms a layer that is physically adsorbed on the surface of the microelectromechanical device.

39. The method of claim 36, wherein the coating agent comprises a first component and a second component, wherein the first component forms a layer that is chemically bonded to the surface of the microelectromechanical device, and the second component of forms another layer that is not chemically bonded to the surface of the microelectromechanical device.

40. The method of claim 31, wherein the modification agent comprises a coating agent that forms a layer, said layer being chemically bonded to the surface of the microelectromechanical device.

41. The method of claim 31, wherein the modification agent comprises a coating agent that forms a layer, said layer being physically adsorbed to the surface of the microelectromechanical device.

42. The method of claim 31, wherein the modification agent comprises a coating agent that further comprises a first component and a second component, said first component forming a layer that is chemically bonded to the surface, and said second component forming another layer that is not chemically bonded to the surface.

43. The method of claim 31, wherein the step of introducing the gaseous modification agent into the chamber further comprises:
a) introducing a first component of the modification agent into the chamber such that the pressure inside the chamber is at a first pressure value; and
b) introducing a second component of the modification agent into the chamber such that the pressure inside the chamber is at a second pressure value that is higher then the first pressure value.

44. The method of claim 43, further comprising:
lowering the pressure inside the chamber to the first pressure or lower; and
repeating the steps a) and b).

45. A method for modifying a surface of a microelectromechanical device, the method comprising:
assembling the microelectromechanical device into an assembly that comprises at least two substrates, one of which is opaque to ultra-violet light;
loading the assembly into a chamber;
preparing a gaseous modification agent; and
introducing the gaseous modification agent into the chamber for modifying the surface of the microelectromechanical device.

46. The method of claim 45, wherein the step of introducing the gaseous modification agent into the chamber further comprises:
introducing the agent onto the surface through a micro-opening of the assembly, wherein the micro-opening has a characteristic dimension around 10 micrometers or less.

47. The method of claim 45, further comprising:
a) introducing a first component of the agent into the chamber such that the pressure inside the chamber is at a first pressure value; and
b) introducing a second component of the agent into the chamber such that the pressure inside the chamber is at a second pressure value that is higher than the first pressure value.

48. The method of claim 47, further comprising:
lowering the pressure inside the chamber to a pressure that is equal to or lower than the first pressure value; and
repeating the steps a) and b).

49. The method of claim 45, wherein the modification agent is a cleaning agent for cleaning the surface of the microelectromechanical device.

50. The method of claim 49, wherein the cleaning agent comprises ozone gas and vapor water.

51. The method of claim 49, wherein the cleaning agent comprises ozone gas in the absence of water.

52. The method of claim 45, wherein the modification agent comprises a coating agent for coating the surface of the microelectromechanical device.

53. The method of claim 52, wherein the coating agent forms a layer that is chemically bonded to the surface of the microelectromechanical device.

54. The method of claim 52, wherein the coating agent forms a layer that is physically adsorbed to the surface of the microelectromechanical device.

55. The method of claim 52, wherein the coating agent comprises a first and second component, said first component being chemically bonded to the surface of the microelectromechanical device, and said second component being not chemically bonded to the surface of the microelectromechanical device.

56. A method for modifying a surface of a microelectromechanical device in an assembly, the method comprising:
loading the assembly into a chamber; and
introducing a gaseous modification agent into the chamber such that the agent is delivered through an opening of the assembly to the surface of the microelectromechanical device, further comprising:
a) introducing a first component of the agent into the chamber at a first pressure; and
b) introducing a second component of the agent into the chamber at a second pressure that is higher than the first pressure.

57. The method of claim 56, further comprising:
pumping out the chamber such that the pressure inside the chamber is equal to or less than the first pressure; and
repeating the steps a) and b).

58. The method of claim 56, wherein the modification agent comprises a gaseous cleaning agent for cleaning the surface.

59. The method of claim 58, wherein the first component of the cleaning agent comprises vapor water and ozone gas.

60. The method of claim 58, wherein the second component of the cleaning agent comprises ozone gas in the absence of vapor water.

61. The method of claim 56, wherein the modification agent comprises a coating agent for coating the surface.

62. The method of claim 61, wherein the coating agent forms a layer that is chemically bonded to the surface of the microelectromechanical device.

63. The method of claim 61, wherein the coating agent forms a layer that is physically adsorbed to the surface of the microelectromechanical device.

64. The method of claim 61, wherein the coating agent comprises first and second component, said first component forming a layer that is chemically bonded to the surface, and said second component forming a layer that is not chemically bonded to the surface.

65. A method for processing a surface of a microelectromechanical device during a packaging process for the microelectromechanical device, the method comprising:
assembling the microelectromechanical device into an assembly;
attaching the assembly to a packaging substrate;
loading the package substrate attached with the assembly into a chamber;
preparing a cleaning agent comprising ozone gas and an oxygen containing co-agent;
introducing the prepared cleaning agent into the chamber for cleaning the surface of the microelectromechanical device in the chamber; and
sealing the microelectromechanical device between the package substrate and a cover lid by bonding the cover lid to the substrate.

66. The method of claim 65, wherein the co-agent is vapor water.

67. The method of claim 65, wherein the step of introducing the cleaning agent into the chamber further comprises:
a) introducing a first component of the cleaning agent into the chamber at a first pressure; and
b) introducing a second component of the cleaning agent into the chamber at a second pressure that is higher than the first pressure.

68. The method of claim 67, further comprising:
lowering the pressure of the chamber to a pressure value that is equal to or lower than the first pressure; and
repeating the steps a) and b).

69. The method of claim 67, wherein the first component comprises ozone gas and vapor water; and wherein the second component comprises ozone gas without vapor water.

70. The method of claim 65, further comprising:
pumping out the chamber; and
filling the chamber with a gas before sealing the chamber.

71. A method for processing a surface of a microelectromechanical device during a packaging process for the microelectromechanical device, the method comprising:
assembling the microelectromechanical device into an assembly;
attaching the assembly to a packaging substrate;
loading the package substrate attached with the assembly into a chamber;
preparing a gaseous modification agent; and
introducing the gaseous modification agent into the chamber such that the cleaning agent is delivered through an micro-opening of the assembly to the surface of the microelectromechanical device for modifying the surfaces of the microelectromechanical device, wherein the micro-opening has a characteristic dimension around 10 micrometers or less; and
sealing the microelectromechanical device between the package substrate and a cover lid by bonding the cover lid to the substrate.

72. The method of claim 71, wherein the step of preparing the gaseous modification agent further comprises:
preparing a cleaning agent and comprising ozone gas and a co-agent that comprises oxygen-containing molecules.

73. The method of claim 72, wherein the step of introducing the gaseous modification agent into the chamber further comprises:
introducing the prepared cleaning agent into the chamber for cleaning the surface of the microelectromechanical device.

74. The method of claim 73, wherein the step of preparing the gaseous modification agent further comprises:
preparing a coating agent that is able to form a coating layer chemically bonded to the surface of the microelectromechanical device.

75. The method of claim 73, wherein the step of preparing the gaseous modification agent further comprises:
preparing a coating agent that is able to form a coating layer physically adsorbed on the surface of the microelectromechanical device.

76. The method of claim 73, wherein the step of preparing the gaseous modification agent further comprises:
preparing a coating agent comprising a first and second components, wherein the first component is able to form a coating layer chemically bonded to the surface of the microelectromechanical device, and the second component is able to form a coating layer physically adsorbed to the surface of the microelectromechanical device.

77. A method for cleaning a surface of a microelectromechanical device, the method comprising:
loading the microelectromechanical device into a chamber; and
cleaning the surfaces of the microelectromechanical device in the chamber using a cleaning agent that comprises ozone gas.

78. The method of claim 77, wherein the microelectromechanical device is within an assembly that comprises a substrate that is opaque to ultra-violet light.

79. The method of claim 77, wherein the cleaning agent further comprises: water vapor.

80. The method of claim 77, wherein the cleaning agent further comprises a chemical species that is selected from a group comprising: hydrogen peroxide vapor and acetic acid vapor.

81. A method for processing a surface of a microelectromechanical device during a packaging process for the microelectromechanical device, the method comprising:
assembling the microelectromechanical device into an assembly that comprises at least two substrates, one of which is opaque to ultra-violet light;
attaching the assembly to a packaging substrate;
loading the package substrate attached with the assembly into a chamber;
preparing a gaseous modification agent; and
introducing the gaseous modification agent into the chamber for modifying the surface of the microelectromechanical device.

82. A system for modifying a microelectromechanical device, the system comprising:
a cleaning agent chamber containing ozone gas;
a co-agent source containing an oxygen containing co-agent;
a coating source containing a coating agent; and
a chamber that is connected to the cleaning source, the co-agent source and the coating source.

83. The system of claim 82, wherein the co-agent source contains water vapor.
